(19) United States
(12) Patent Application Publication
(10) Pub. No.: US 2025/0221266 A1
(43) Pub. Date: Jul. 3, 2025

(54) Display Device

(71) Applicant: LG Display Co., Ltd., Seoul (KR)

(72) Inventors: KyoungJin Park, Paju-si (KR); Jaehyuk Lee, Paju-si (KR); Hyein Park, Gwangju (KR)

(21) Appl. No.: 18/971,889

(22) Filed: Dec. 6, 2024

(30) Foreign Application Priority Data
Dec. 29, 2023 (KR) 10-2023-0197173

(51) Int. Cl. H10K 59/80; H10K 59/124

(52) U.S. Cl. CPC H10K 59/873; H10K 59/124; H10K 59/80521

(57) ABSTRACT

A display device comprises a substrate comprising an display area and a non-display area, a planarization layer on the substrate and extends to the non-display area, an organic layer on the planarization layer, a cathode on the organic layer, a capping layer on the cathode, a first inorganic encapsulation layer on the capping layer, and a second inorganic encapsulation layer on the first inorganic encapsulation layer to contact the first inorganic encapsulation layer, a side of the planarization layer, a side of the organic layer, a side of the cathode, a side of the capping layer and a side of the first inorganic encapsulation layer, wherein the first inorganic encapsulation layer is an etch mask in an etch process, so that the planarization layer, the organic layer, the cathode or the capping layer in an unnecessary shadow area caused by use of a deposition mask may be etched.

### CROSS-REFERENCE TO RELATED APPLICATION

This application claims the priority of Republic of Korea Patent Application No. 10-2023-0197173 filed on Dec. 29, 2023, which is hereby incorporated by reference in its entirety.

### BACKGROUND

### Field

The present disclosure relates to a display device, and particularly, a display device in which the size of a bezel area decreases.

### Description of the Related Art

In the information era, the field of display device displaying electric information signals visually has made a rapid progress, and research has been conducted into a variety of display devices that are thin and lightweight and ensure less power consumption and the like, to enhance their performance.

A typical display device comprises a liquid crystal display device (LCD), an electro-wetting display device (EWD), an organic light emitting display device (OLED) and the like.

Additionally, in a display device, a minimum bezel area, i.e., a minimum non-display area, is required to secure reliability in moisture-infiltration prevention and the like. However, since the non-display area is an area that does not display an image, there is a growing demand for a display device in which the size of a display area increases while the size of a non-display area decreases, to provide a screen offering a greater immersive feeling to the user and enhance aesthetic qualities of a product.

### SUMMARY

An object to be achieved by the embodiment of the present disclosure is to provide a display device in which a non-display area as a bezel area decreases.

Another object to be achieved by the embodiment of the present disclosure is to provide a display device in which moisture-infiltration prevention performance does not deteriorate although a non-display area decreases.

Objects of the present disclosure are not limited to the above-mentioned objects, and other objects, which are not mentioned above, can be clearly understood by those skilled in the art from the following descriptions.

A display device of one embodiment may comprise a substrate comprising an display area and a non-display area surrounding the display area, a planarization layer disposed on the substrate and extended to the non-display area from the display area, an organic layer disposed on the planarization layer, a cathode disposed on the organic layer, a capping layer disposed on the cathode, a first inorganic encapsulation layer disposed on the capping layer, and a second inorganic encapsulation layer disposed on the first inorganic encapsulation layer to contact the first inorganic encapsulation layer, and disposed to contact a side of the planarization layer, a side of the organic layer, a side of the cathode, a side of the capping layer and a side of the first inorganic encapsulation layer.

Other detailed matters of the exemplary embodiments are included in the detailed description and the drawings.

According to the present disclosure, the first inorganic encapsulation layer as an etch mask is disposed on the capping layer, and the planarization layer, the organic layer, the cathode or the capping layer in an unnecessary shadow area caused by use of a deposition mask is etched, so that a bezel distance is secured. Thus, according to the present disclosure, the width of a bezel decreases, and reliability in moisture-infiltration prevention performance improves.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a display device according to one embodiment;

FIG. 2 is a cross-sectional view of a sub pixel in the display device according to one embodiment;

FIG. 3 is a cross-sectional view along III-III′ in FIG. 1 according to one embodiment;

FIG. 4 is a cross-sectional view of a display device according to another embodiment;

FIG. 5 is a cross-sectional view of a display device according to another embodiment;

FIG. 6 is a cross-sectional view of a display device according to another embodiment;

FIG. 7 is a cross-sectional view of a sub pixel in a display device according to another embodiment;

FIG. 8 is a cross-sectional view of a display device according to another embodiment;

FIG. 9 is a cross-sectional view of a display device according to another embodiment;

FIG. 10 is a cross-sectional view of a display device according to another embodiment; and

FIG. 11 is a cross-sectional view of a display device according to yet another embodiment.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

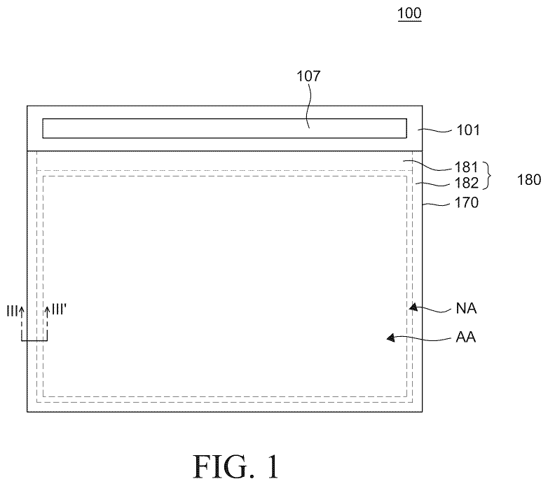

FIG. 1 is a plan view of a display device according to one embodiment.

Referring to FIG. 1, a display device 100 of one embodiment may comprise a substrate 101, an encapsulation substrate 170, a pad part 107, and a dam 180.

The display device 100 is a device for displaying an image to the user.

In the display device 100, a display element for displaying an image, a driving element for driving the display element, lines delivering various types of signals to the display element and the driving element, and the like are disposed. The display element may be defined differently depending on the sort of display device 100, and in the case where the display device 100 is an organic light emitting display device, for example, the display element may be an organic light emitting diode comprising an anode, an organic light emitting layer (or an organic layer) and a cathode. For example, in the case where the display device 100 is a liquid crystal display device, the display element may be a liquid crystal display element. Hereinafter, suppose that the display device 100 is an organic light emitting display device, but not limited thereto.

The display device 100 may comprise a display area AA and a non-display area NA.

The display area AA is an area where an image is displayed, in the display device 100.

In the display area AA, a plurality of sub pixels constituting a plurality of pixels, and a circuit for driving the plurality of sub pixels may be disposed. The plurality of sub pixels are a minimum unit constituting the display area AA, a display element may be disposed in each of the plurality of sub pixels, and the plurality of sub pixels may constitute a pixel. For example, an organic light emitting diode comprising an anode, an organic light emitting layer and a cathode may be disposed in each of the plurality of sub pixels, but not limited thereto. Additionally, a driving element and lines and the like may be included in a circuit for driving the plurality of sub pixels. For example, the circuit may be comprised of a thin film transistor, a storage capacitor, gate lines, data lines and the like, but not limited thereto.

The non-display area is an area where an image is not displayed.

In FIG. 1, the non-display area NA surrounds the display area AA shaped into a rectangle, but the shapes and disposition of the display area AA and the non-display area NA are not limited to those provided as examples in FIG. 1.

In other words, the display area AA and the non-display area NA may be formed to be appropriate for designing an electronic device equipped with a display device 100. For example, the display area AA may be shaped into a pentagon, a hexagon, a circle, an ovel and the like, for example.

In the non-display area NA, a variety of lines, circuits and the like for driving an organic light emitting diode in the display area AA may be disposed. For example, the non-display area NA may include link lines for delivering signals to the plurality of sub pixels and the circuits in the display area AA, driving ICs such as a gate driver IC and a data driver IC, or a pad part 107 and the like, but not limited thereto.

The display device 100 may comprise a variety of additional elements for generating a variety of signals or driving a pixel in the display area AA. An additional element for driving a pixel may comprise an inverter circuit, a multiplexer, an electrostatic discharge (ESD) circuit and the like. The display device 100 may comprise an additional element relevant to a function in addition to the function of driving a pixel. For example, the display device 100 may comprise additional elements providing a touch sensing function, a user authentication function (e.g., fingerprint recognition), a multi-level pressure sensing function, a tactile feedback function and the like. The above-mentioned additional elements may be placed in an external circuit connecting to the non-display area (NA) and/or a connection interface.

The pad part 107 may be provided to receive signals from the outside. Accordingly, the pad part 107 may be disposed in the non-display area NA of the display device 100, and electrically connect to a variety of lines and circuits and a printed circuit board that are disposed in the display area AA. For example, the pad part 107 may perform the function of delivering a signal to each of the gate lines and data lines and may be comprised of a gate pad for delivering gate signals to the gate lines, and a data pad for delivering data signals to the data lines, but not limited thereto.

Additionally, in the display device 100 of one embodiment, a dam 180 may be provided in the non-display area NA to ensure reliability in prevention of the infiltration of moisture and the like.

The dam 180 may comprise a first dam 181 disposed between the display area AA and the pad part 107, and a second dam 182 connecting to one side and the other side of the first dam 181 and surrounding the display area AA, but not be limited thereto. The first dam 181 and the second dam 182 are specifically described hereinafter with reference to FIG. 1.

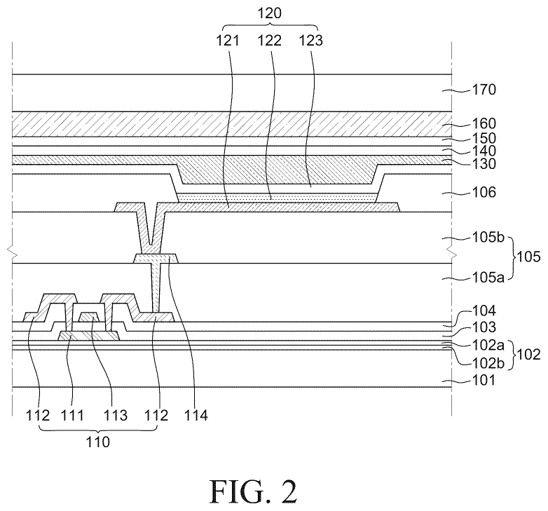

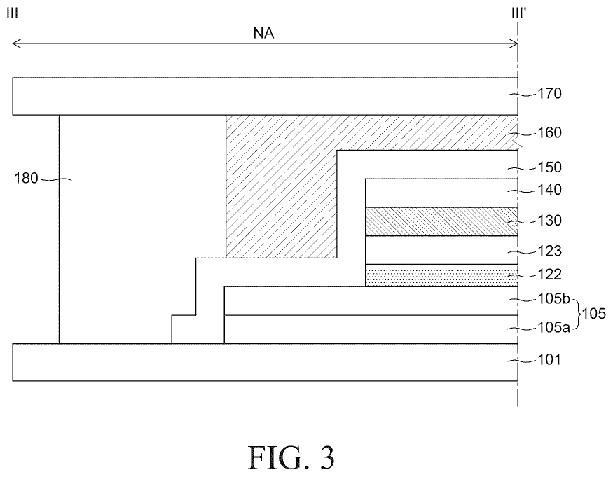

The display device 100 of one embodiment may be embodied based on a top emission method. In the top emission method, a reflective electrode formed of an opaque and electrically conductive material having high reflectivity, e.g., silver (Ag), aluminum (Al), gold (Au), molybdenum (Mo), tungsten (W), chromium (Cr) or an alloy thereof and the like may be disposed in the lower portion of the anode/under the anode so that light emitting from the organic layer is reflected by the anode to proceed upward, i.e., toward the cathode located at the upper portion. Hereinafter, suppose that the display device 100 of one embodiment is based on the top emission method. Further, the display device of one embodiment is specifically described hereinafter with reference to FIGS. 2 and 3.

FIG. 2 is a cross-sectional view of a sub pixel in the display device according to one embodiment.

FIG. 3 is a cross-sectional view along III-III′ in FIG. 1.

In FIG. 3, each of the elements in the non-display area (NA) is schematically illustrated for convenience of description, but in addition to the illustrated elements, various types of elements may be further included in the non-display area (NA).

Referring to FIGS. 2 and 3, in the case of a display device (100 of FIG. 1) of one embodiment, a driving element 110 may be disposed over the substrate 101.

Additionally, a planarization layer 105 may be disposed on the driving element 110.

Further, an organic light emitting diode 120 electrically connecting with the driving element 110 may be disposed on the planarization layer 105, and a capping layer 130 may be disposed on the organic light emitting diode 120.

A first inorganic encapsulation layer 140 and a second inorganic encapsulation layer 150 may be consecutively disposed on the capping layer 130.

Further, an adhesive layer 160 and an encapsulation substrate 170 may be consecutively disposed on the second inorganic encapsulation layer 150. However, the stack structure of the display device 100 of one embodiment is not limited to the above-described one.

The substrate 101 may be a glass or plastic substrate. A polyimide-based material or a polycarbonate-based material may be used for a plastic substrate to have flexibility. In particular, polyimide may be applied in a high-temperature process, and as a coatable material, widely used for a plastic substrate.

A buffer layer 102 may be disposed on the substrate 101.

The buffer layer 102, as a functional layer for protecting various types of electrodes and lines from impurities such as alkali ions and the like leaking from the substrate 101 or the layers thereunder, may have a multi-layered structure comprised of a first buffer layer 102a and a second buffer layer 102b, but not be limited thereto. The buffer layer 102 may be comprised of multiple layers of silicon oxide (SiOx), silicon nitride (SiNx) or a combination thereof.

The buffer layer 102 may delay the spread of moisture and/or air infiltrated into the substrate 101. Additionally, the buffer layer 102 may comprise a multi buffer and/or an active buffer. The active buffer may protect an active layer 111 comprised of semiconductors of the driving element 110 and block various type of defects coming from the substrate 101. The active buffer may be formed of amorphous silicon (a-Si) and the like.

The driving element 110 may have a shape in which the active layer 111, a gate insulation layer 103, a gate electrode 113, an interlayer insulation layer 104, a source electrode and a drain electrode 112 are disposed consecutively, and electrically connect with the organic light emitting diode 120 through a connection electrode 114 and deliver currents or signals to the organic light emitting diode 120.

The active layer 111 may be disposed on the buffer layer 102. The active layer 111 may be made of poly silicon (p-Si), and at this time, a predetermined area may be doped with impurities. Additionally, the active layer 111 may be comprised of amorphous silicon (a-Si), or an organic semiconductor material such as pentacene and the like. Further, the active layer 111 may be comprised of an oxide semiconductor.

Additionally, the gate insulation layer 103 may be disposed on the active layer 111. The gate insulation layer 103 may be formed of an inorganic insulation material such as silicon oxide (SiOx) or silicon nitride (SiNx) and the like and may also be formed of an organic insulation material and the like.

The gate electrode 113 may be placed on the gate insulation layer 103. The gate electrode 113 may be formed of a variety of electrically conductive materials, e.g., magnesium (Mg), aluminum (Al), nickel (Ni), chromium (Cr), molybdenum (Mo), tungsten (W), gold (Au) or an alloy thereof and the like.

Additionally, the interlayer insulation layer 104 may be placed on the gate electrode 113. The interlayer insulation layer 104 may be formed of an insulation material such as silicon oxide (SiOx) or silicon nitride (SiNx) and the like and may also be formed of an organic insulation material and the like.

The gate insulation layer 103 and the interlayer insulation layer 104 are selectively removed, to form a contact hole to which source and drains areas are exposed. The source electrode and the drain electrode 112 may be formed on the interlayer insulation layer 104 and shaped into a single-layered or multi-layered structure of a material for an electrode. When necessary, an additional protective layer (a passivation layer) comprised of an inorganic insulation material may be formed to cover the source electrode and the drain electrodes 112.

The planarization layer 105 may be disposed on the driving element 110 structured as described above.

The planarization layer 105 may have a multi-layered structure comprised of at least two layers. That is, the planarization layer 105, for example, may comprise a first planarization layer 105a and a second planarization layer 105b. While the first planarization layer 105a is disposed to cover the driving element 110, in such a way that a part of the source electrode and a part of the drain electrode 112 of the driving element 110 are exposed.

The planarization layer 105 may extend to the non-display area (NA).

The planarization layer 105 may be an overcoat layer, but not limited thereto.

Additionally, the connection electrode 114 for electrically connecting the driving element 110 and the organic light emitting diode 120 may be disposed on the first planarization layer 105a. Further, though not illustrated in FIG. 2, a variety of metal layers serving as a wire/an electrode of the data lines, the signal lines and the like may be disposed on the first planarization layer 105a.

Further, the second planarization layer 105b may be disposed on the first planarization layer 105a and the connection electrode 114. The planarization layer 105 of one embodiment is comprised of two layers, since the number of various types of signal lines increases as the resolution of the display device 100 becomes higher. Accordingly, it is difficult to dispose all the lines in one layer while a minimum gap between the lines is secured. That is why an additional layer is made. The addition of such an additional layer (i.e., the second planarization layer 105b) creates room for disposing the lines, making it easier to design the disposition of the lines/electrodes. Further, in the case where a dielectric material is used for the planarization layer 105 having a multi-layered structure, the planarization layer 105 may be used to form electrostatic capacity between the metal layers.

The second planarization layer 105b may be formed in such a way that a part of the connection electrode 114 is exposed, and the drain electrode 112 of the driving element 110 and an anode 121 of the organic light emitting diode 120 may be electrically connected by the connection electrode 114.

The organic light emitting diode 120 may be constituted in such a way that the anode 121, a plurality of organic layers 122 and a cathode 123 are disposed consecutively. That is, the organic light emitting diode 120 may be comprised of the anode 121 formed on the planarization layer 105, the organic layer 122 formed on the anode 121, and the cathode 123 formed on the organic layer 122.

A bank 106 may be formed in a remaining area expect for a light emitting area, on the planarization layer 105. That is, the bank 106 has a bank hole that exposes the anode 121 corresponding to the light emitting area. The bank 106 may be comprised of an inorganic insulation material such as silicon nitride (SiNx) and silicon oxide (SiOx) or an organic insulation material such as a BCB, an acryl-based resin or an imide-based resin.

Though not illustrated, the bank 106 may extend to the non-display area NA.

The organic layer 122 may be disposed on the anode 121 exposed by the bank 106. The organic layer 122 may comprise a light emitting layer, an electron injection layer, an electron transport layer, a hole transport layer, a hole injection layer and the like.

The organic layer 122 may extend to the non-display area NA.

In the non-display area NA, the organic layer 122 may be disposed on the planarization layer 105.

The cathode 123 may be disposed on the organic layer 122.

In the top emission method, the cathode 123 may comprise a transparent and electrically conductive material. For example, the cathode 123 may be comprised of indium tin oxide (ITO), indium zinc oxide (IZO), indium gallium zinc oxide (IGZO) and the like. Alternatively, the cathode 153 may be constituted in such a way that a layer comprised of a transparent and electrically conductive material such as indium tin oxide (ITO), indium zinc oxide (IZO), indium gallium zinc oxide (IGZO), and a layer comprised of a metal material such as gold (Au), silver (Ag), aluminum (Al), palladium (Pd), molybdenum (Mo), magnesium (Mg), copper Cu) and the like or an alloy thereof are stacked, but not limited thereto. The cathode 123 may extend to the non-display area NA.

The capping layer 130 may be disposed on the cathode 123. The capping layer 130 may be comprised of a material of a high refractive index and a high light absorption rate, to reduce scattered reflection of external light.

The first inorganic encapsulation layer 140 and the second inorganic encapsulation layer 150 may be consecutively disposed on the capping layer 130.

The first inorganic encapsulation layer 140 and the second inorganic encapsulation layer 150 prevent or at least reduce air or moisture from infiltrating into the organic light emitting diode 120. Accordingly, each of the first inorganic encapsulation layer 140 and the second inorganic encapsulation layer 150, for example, may be comprised of an inorganic insulation material such as silicon nitride (SiNx), silicon oxide (SiOx), silicon oxynitride (SiON) or aluminum oxide (Al2O3), but not limited thereto.

The first inorganic encapsulation layer 140 may serve as an ashing mask in a manufacturing process. Since an etch process is performed in the state where the first inorganic encapsulation layer 140 is disposed on the capping layer 130, one or more of the organic layer 122, the cathode 123 and the capping layer 130 that protrude further outward than the first inorganic encapsulation layer 140 may be etched. Accordingly, the side of one or more of the organic layer 122, the cathode 123 and the capping layer 130 may be disposed on the same planar surface as the side of the first inorganic encapsulation layer 140. That is, referring to FIG. 3, the sides of the first inorganic encapsulation layer 140, the organic layer 122, the cathode 123 and the capping layer 130 may be disposed on the same planar surface, for example. However, the structure of the display device 100 of one embodiment is not limited to the above-described one.

Additionally, the second inorganic encapsulation layer 150 may be disposed on the first inorganic encapsulation layer 140 in such a way that the second inorganic encapsulation layer 150 contacts the first inorganic encapsulation layer 140. Further, the second inorganic encapsulation layer 150 may be disposed in such a way that the second inorganic encapsulation layer 150 contacts the side of the planarization layer 105, the side of the organic layer 122, the side of the cathode 123, the side of the capping layer 130 and the side of the first inorganic encapsulation layer 140. That is, the second inorganic encapsulation layer 150 may be disposed to cover all the elements disposed under the second inorganic encapsulation layer 150 completely.

An adhesive layer 160 and an encapsulation substrate 170 may be disposed on the second inorganic encapsulation layer 150. The adhesive layer 160 may fill a space between the second inorganic encapsulation layer 150 and the encapsulation substrate 170. The adhesive layer 160 may comprise an adhesive resin. The adhesive resin may be comprised of a material exhibiting adhesion and may be a thermally cured resin or a naturally cured resin. For example, the adhesive resin may be comprised of an optical clear adhesive (OCA), a pressure sensitive adhesive (PSA) and the like, but not limited thereto.

Additionally, the adhesive layer 160 may protect the organic light emitting diode 120 of the pixel part from external moisture, air, impacts and the like, together with the first inorganic encapsulation layer 140, the second inorganic encapsulation layer 150 and the encapsulation substrate 170. The adhesive layer 160 may further comprise a moisture absorber. The moisture absorber may be particles having hygroscopicity, and absorb moisture, air and the like from the outside and minimize the infiltration of the moisture and air into the pixel part, but not limited thereto.

The adhesive layer 160 may comprise a filler.

That is, the filler may be formed of a transparent material, to prevent deterioration in luminance in the process where light emitting from the organic light emitting diode 120 is transmitted into the encapsulation substrate 170. For example, the filler may be comprised of epoxy or olefin, or may comprise talc, calcium oxide (CaO), barium oxide (BaO), zeolite, silicon oxide (SiO) and the like.

The encapsulation substrate 170 may be disposed on the adhesive layer 160.

The encapsulation substrate 170 may protect the organic light emitting diode 120 of the pixel part, together with the adhesive layer 160. The encapsulation substrate 170 may protect the organic light emitting diode 120 from external moisture, air, impacts and the like. The encapsulation substrate 170 may be disposed on the substrate 101 in such a way that the pad part (107 of FIG. 1) disposed at one side of the substrate 101 is exposed.

A dam 180 is disposed between the substrate 101 and the encapsulation substrate 170 at the edge of the substrate 101 to improve adhesion between the substrate 101 and the encapsulation substrate 170 and block moisture.

The dam 180 may be disposed in the non-display area NA outside the display area AA. That is, the dam 180 may be formed to surround the adhesive layer 160 between the substrate 101 and the encapsulation substrate 170, and together with the adhesive layer 160, may bond and seal the substrate 101 and the encapsulation substrate 170. Accordingly, the dam 180 may be disposed in an area where the substrate 101 and the encapsulation substrate 170 overlap. Further, the lower surface of the dam 180 may contact the substrate 101 and the second inorganic encapsulation layer 150.

The dam 180 may comprise a first dam (181 of FIG. 1) and a second dam (182 of FIG. 1).

The first dam 181 may be disposed between the display area AA and the pad part 107. For example, the first dam 181 may be disposed along the edge of the upper side of the encapsulation substrate 170 that is disposed to expose the pad part 107. For example, the first dam 181 may be disposed to be adjacent to one side among four sides of the display device 100.

The second dam 182 may connect to one side and the other side of the first dam 181 and be disposed to surround the display area AA. For example, the second dam 182 may be disposed along the edges of the lower side and the left and right sides of the display device 100. For example, the second dam 182 may be disposed to be adjacent to three sides among four sides of the display device 100.

In the case where the organic layer 122 of the organic light emitting diode 120 is exposed to moisture or air, its properties are degraded rapidly. To prevent this from happening, a minimum bezel distance is needed to secure reliability in preventing or at least reducing the infiltration of moisture and the like in the display device 100, and this may be referred to as a reliable bezel. That is, the reliable bezel may be defined from the end of the encapsulation substrate 170 to the end of the cathode 123.

Additionally, at a time when there is a growing demand for a slim display device 100, a slim non-display area NA of the display device 100 is required. However, in the case where the cathode 123 is formed to cover the organic layer 122, to prevent or at least reduce failure of display device 100 caused by exposure of the organic layer 122, securing a reliable bezel is limited. In the case where the organic layer 122 and the cathode 123 are formed based on deposition, a shadow area of a predetermined length is created depending on a gap and a deposition method between a deposition mask and the substrate 101, making it difficult to reduce a bezel. Further, the position and length of the shadow area are not uniform, due to a process deviation, and a product quality is not uniform due to a difference in the reliable bezel of each product.

To prevent this from happening, in the display device 100 of one embodiment, the first inorganic encapsulation layer 140 as an etch mask is disposed on the capping layer 130. The planarization layer 105, the organic layer 122, the cathode 123 and the capping layer 130 may be etched so that the side of one or more of the planarization layer 105, the organic layer 122, the cathode 123 and the capping layer 130 disposed under the first inorganic encapsulation layer 140 may be disposed on the same planar surface as the side of the first inorganic encapsulation layer 140, in the state where the first inorganic encapsulation layer 140 is disposed. Since in the display device 100 of one embodiment, the side of one or more of the planarization layer 105, the organic layer 122, the cathode 123 and the capping layer 130 is disposed at the same position as the side of the first inorganic encapsulation layer 140, the length of the shadow area my decrease. Accordingly, the surface area of the entire non-display area NA may decrease, and as a result, the width of the bezel may decrease.

Further, in the display device 100 of one embodiment, although the non-display area NA decreases as a bezel distance decreases, reliability in preventing the infiltration of moisture and the like may be secured since the width of the dam 180 is maintained or rather increased. Furthermore, since the first inorganic encapsulation layer 140 and the second inorganic encapsulation layer 150 contact each other, the infiltration of moisture in the lateral direction of the display device 100 may be delayed further. In particular, since the second inorganic encapsulation layer 150 is disposed to contact the side of the planarization layer 105, the side of the organic layer 122, the side of the cathode 123, the side of the capping layer 130 and the side of the first inorganic encapsulation layer 140, the inside of the second inorganic encapsulation layer 150 may be sealed. Thus, the display device 100 of one embodiment may ensure reliability as well as prevention of the infiltration of moisture.

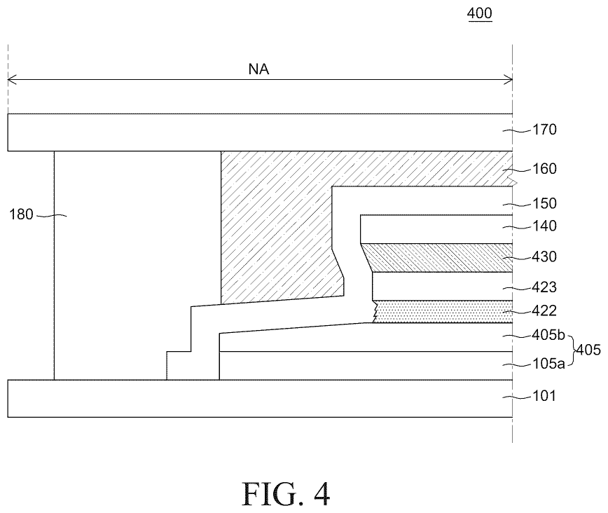

FIG. 4 is a cross-sectional view of a display device according to another embodiment.

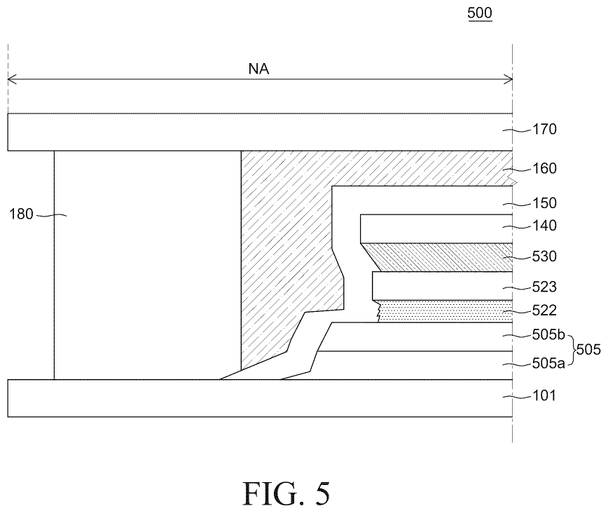

FIG. 5 is a cross-sectional view of a display device according to another embodiment.

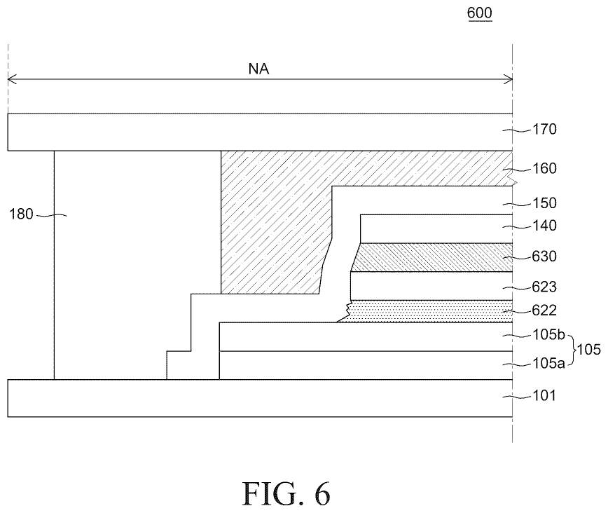

FIG. 6 is a cross-sectional view of a display device according to another embodiment.

FIGS. 4-6 are cross-sectional views of a display device 400, 500, 600 of various embodiments.

The elements of the display devices 400, 500, 600 of various embodiments in FIGS. 4-6 are the same as those of the above-described display device 100 of one embodiment in FIGS. 1-3, except for a planarization layer 405, 505, an organic layer 422, 522, 622, a cathode 423, 523, 623 and a capping layer 430, 530, 630. That is, the other elements except for the planarization layer 405, 505, the organic layer 422, 522, 622, the cathode 423, 523, 623 and the capping layer 430, 530, 630 are substantially the same, and accordingly, description of the other elements is omitted. Additionally, identical elements are given identical reference numerals. Hereinafter, FIGS. 1-3 can be referred to for description of the identical reference numerals.

Further, as the etch process proceeds in the state where the first inorganic encapsulation layer 140 is disposed on the capping layer 430, 530, 630, one or more of the planarization layer 405, 505, the organic layer 422, 522, 622, the cathode 423, 523, 623 and the capping layer 430, 530, 630 protruding further outward than the first inorganic encapsulation layer 140 may be etched. At this time, each of the layers may be comprised of a different material, and accordingly, the degree of etching may vary depending on each of the layers. Thus, each of the layers may have a different shape.

Further, in FIGS. 4 and 5, the end of the first inorganic encapsulation layer 140 may be disposed to protrude further outward than the end of one or more of the organic layer 422, the cathode 423 and the capping layer 430.

Referring to FIG. 4, the end of the planarization layer 405 of the display device 400 of another embodiment may be disposed to protrude further outward than the end of the organic layer 422. Additionally, in the process where the organic layer 422, the cathode 423 or the capping layer 430 is etched, the upper surface of a second planarization layer 405b may also be partially etched.

Accordingly, the upper surface of the second planarization layer 405b may comprise an inclination surface that inclines toward the substrate 101 in the area where the second planarization layer 405b protrudes further than the end of the organic layer 422.

In the display device 400 of another embodiment, the end of the organic layer 422 may be disposed further inward than the end of the first inorganic encapsulation layer 140. At this time, the inward side may denote an inward direction facing the display area AA. Further, the side of the organic layer 422 may include an irregular convex and concave part. This is because of a different etch ratio of a variety of layers such as a light emitting layer, an electron injection layer, an electron transport layer, a hole transport layer, a hole injection layer and the like that may be included in the organic layer 422. That is, a different etch ratio of various layers included in the organic layer 422 results in a different degree to which the end of each of the layers protrudes in the etch process that is carried out by using the first inorganic encapsulation layer 140 as a mask, so that the organic layer 422 has an irregular convex and concave part on the side thereof.

In the display device 400 of another embodiment, the end of the cathode 423 may be disposed further inward than the end of the first inorganic encapsulation layer 140. Additionally, the side of the cathode 423 may include an irregular convex and concave part that is less rough than the irregular convex and concave part on the side of the organic layer 422 or may not, and may have a cross section of a straight line, but not be limited thereto.

In the display device 400 of another embodiment, the end of the capping layer 430 may also be disposed further inward than the end of the first inorganic encapsulation layer 140. For example, the side of the capping layer 430 may be formed to incline inward toward the lower surface thereof. That is, the end of the lower surface of the capping layer 430 may be disposed further inward than the end of the upper surface thereof. The end of the upper surface of the capping layer 430 may be aligned with the end of the lower surface of the first inorganic encapsulation layer 140. Additionally, the end of the lower surface of the capping layer 430 may be aligned with the end of the upper surface of the cathode 423.

In the display device 400 of another embodiment, the ends of the organic layer 422, the cathode 423, and the capping layer 430 are disposed further inward than the end of the first inorganic encapsulation layer 140, so that the surface area of the non-display area NA decreases further. Accordingly, the width of the bezel may decrease. Further, although the non-display area NA decreases, moisture-infiltration prevention performance may be maintained or rather increased while reliability may be secured.

Referring to FIG. 5, the end of the planarization layer 505 of a display device 500 of another embodiment may protrude further outward than the first inorganic encapsulation layer 140. For example, in the process where the organic layer 522, the cathode 523 or the capping layer 530 described hereinafter is etched, a first planarization layer 505a and a second planarization layer 505b may also be etched. Accordingly, the sides of the first planarization layer 505a and the second planarization layer 505b may include an inclination surface that inclines toward the substrate 101. At this time, the inclination surface may be provided as a single one or as one or more ones.

In the display device 500 of another embodiment, the end of the organic layer 522 may be disposed further inward than the end of the first inorganic encapsulation layer 140. Additionally, the end of the upper surface of the organic layer 522 may protrude further outward than the end of the lower surface thereof. For example, the length of the upper surface of the organic layer 522 may be greater than the length of the lower surface of the organic layer 522, on a cross section. Further, the side of the organic layer 522 may include an irregular convex and concave part. This is because of a different etch ratio of a variety of layers such as a light emitting layer, an electron injection layer, an electron transport layer, a hole transport layer, a hole injection layer and the like that may be included in the organic layer 522. That is, a different etch ratio of various layers included in the organic layer 522 results in a different degree to which the end of each of the layers protrudes in the etch process that is carried out by using the first inorganic encapsulation layer 140 as a mask, so that the organic layer 522 has an irregular convex and concave part on the side thereof.

The end of the cathode 523 may be disposed further inward than the end of the first inorganic encapsulation layer 140. Additionally, the side of the cathode 523 may not include an irregular convex and concave part and may have a straight-line shape on a cross section.

In the display device 500 of another embodiment, the side of the capping layer 530 may be formed to incline inward toward the lower surface thereof. That is, on a cross section, the length of the upper surface of the capping layer 530 may be greater than the length of the lower surface thereof. Additionally, the end of the upper surface of the capping layer 530 may be aligned with the end of the lower surface of the first inorganic encapsulation layer 140. For example, the end of the upper surface of the cathode 523 may be disposed to protrude further outward than the end of the lower surface of the capping layer 530, but not limited thereto.

In the display device 500 of another embodiment, the ends of the organic layer 522, the cathode 523 and the capping layer 530 are disposed further inward than the end of the first inorganic encapsulation layer 140, and the end of the planarization layer 505 may also be disposed further inward than the end of the planarization layer of the above-described embodiments, so that the surface area of the non-display area NA decreases further. Accordingly, the width of the bezel may decrease further. Further, although the non-display area NA decreases, moist-infiltration prevention performance may be maintained or rather increased while reliability may be secured.

Referring to FIG. 6, in the display device 600 of another embodiment, the end of one or more of the organic layer 622, the cathode 623 and the capping layer 630 may be disposed to protrude further outward than the end of the first inorganic encapsulation layer 140.

The end of the organic layer 622 of the display device 600 of another embodiment may be disposed to protrude further outward than the end of the first inorganic encapsulation layer 140. For example, on a cross section, the length of the upper surface of the organic layer 622 may be less than the length of the lower surface thereof. That is, the end of the lower surface of the organic layer 622 may be disposed to protrude further outward than the end of the upper surface thereof.

Additionally, the side of the organic layer 622 may include an irregular convex and concave part. This is because of a different etch ratio of various layers such as a light emitting layer, an electron injection layer, an electron transport layer, a hole transport layer, a hole injection layer and the like that may be included in the organic layer 622, as described above. For example, a different etch ratio of various layers included in the organic layer 622 results in a different degree to which the end of each of the layers protrudes in the etch process that is carried out by using the first inorganic encapsulation layer 140 as a mask, so that the organic layer 622 has an irregular convex and concave part on the side thereof.

The end of the cathode 623 of the display device 600 of another embodiment may protrude further outward than the end of the first inorganic encapsulation layer 140. Additionally, the side of the cathode 623 may not have an irregular convex and concave part and may have a straight-line shape on a cross section.

The end of the capping layer 630 of the display device 600 of another embodiment may protrude further outward than the end of the first inorganic encapsulation layer 140. For example, the side of the capping layer 630 may be formed to incline in such a way that the side of the capping layer 630 protrudes outward further toward the lower surface thereof. That is, on a cross section, the length of the upper surface of the capping layer 630 may be less than the length of the lower surface thereof. Additionally, the end of the upper surface of the capping layer 630 may be aligned with the end of the lower surface of the first inorganic encapsulation layer 140, and the end of the lower surface of the capping layer 630 may be aligned with the end of the upper surface of the cathode 623, but not limited thereto.

In the case of a display device 600 of another embodiment, the organic layer 622, the cathode 623, and the capping layer 630 are etched in the etch process, so that the surface area of the non-display area NA decreases further. Accordingly, the width of the bezel may decrease. Further, although the non-display area NA decreases, moisture-infiltration prevention performance may be maintained or rather increased while reliability may be secured.

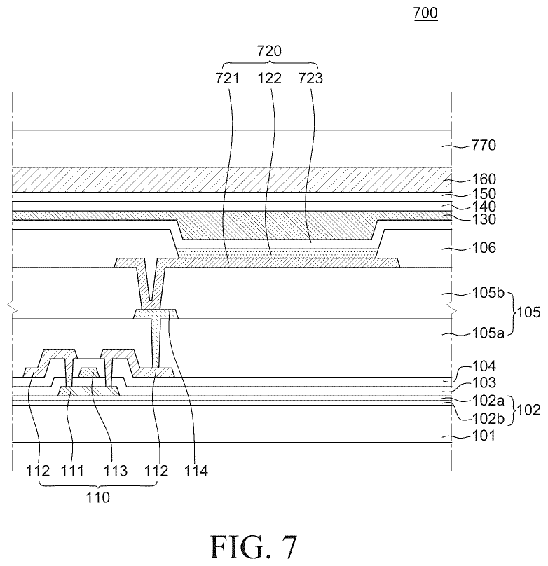

FIG. 7 is a cross-sectional view of a sub pixel in a display device according to another embodiment.

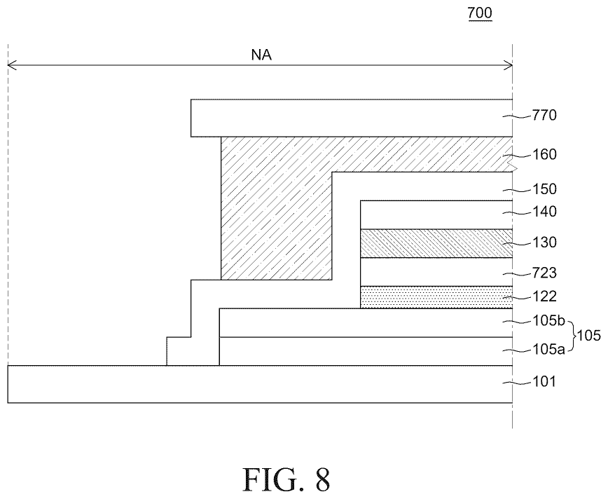

FIG. 8 is a cross-sectional view of a display device according to another embodiment.

A display device 700 of another embodiment in FIGS. 7 and 8 may be embodied based on a bottom emission method. For example, in the bottom emission method, light emitting from the organic layer 722 may be irradiated downward toward the substrate 101. Hereinafter, suppose that the display device 700 is based on the bottom emission method.

The elements of the display device 700 of another embodiment in FIGS. 7 and 8 are the same as those of the display device 100 of one embodiment in FIGS. 1-3, except for an organic light emitting diode 720 and an encapsulation substrate 770. That is, the other elements except for the organic light emitting diode 720 and the encapsulation substrate 770 are substantially the same, and accordingly, description of the other elements is omitted. Further, identical elements are given identical reference numerals. Hereinafter, FIGS. 1-3 can be referred to for description of the identical reference numerals.

Referring to FIGS. 7 and 8, in the display device 700 of another embodiment, the organic light emitting diode 720 may comprise an anode 721, an organic layer 122 and a cathode 723.

The anode 721 of another embodiment may be comprised only of a transparent and electrically conductive material such as indium tin oxide (ITO), indium zinc oxide (IZO), indium gallium zinc oxide (IGZO) and the like.

Additionally, the cathode 732 of another embodiment may comprise any one of a group consisting of a metal material such as gold (Au), silver (Ag), aluminum (Al), molybdenum (Mo), magnesium (Mg), palladium (Pd), copper (Cu) and the like or an alloy thereof.

The encapsulation substrate 770 of another embodiment may protect the organic light emitting diode 720 from an external impact and prevent foreign substances, moisture, air and the like from infiltrating. The encapsulation substrate 770 may be comprised of a metal material such as aluminum (Al), nickel (Ni), chromium (Cr), iron (Fe), an alloy of nickel and the like that have high corrosion resistance and are readily processed in the form of foil or a thin film.

Additionally, a dam may be further formed between the encapsulation substrate 770 and the substrate 101 to enhance performance of preventing infiltration of foreign substances, moisture, air and the like. The structure and disposition of the dam may be the same as or similar to those of the dam 180 illustrated in FIGS. 3-6.

In the display device 700 of another embodiment, the ends of the organic layer 122, the cathode 723 and the capping layer 130 are disposed on the same planar surface as the first inorganic encapsulation layer 140, so that the surface area of the non-display area NA decreases. Accordingly, the width of the bezel may decrease. Further, although the non-display area NA decreases, moisture-infiltration prevention performance may be maintained or rather increased, while reliability may be secured.

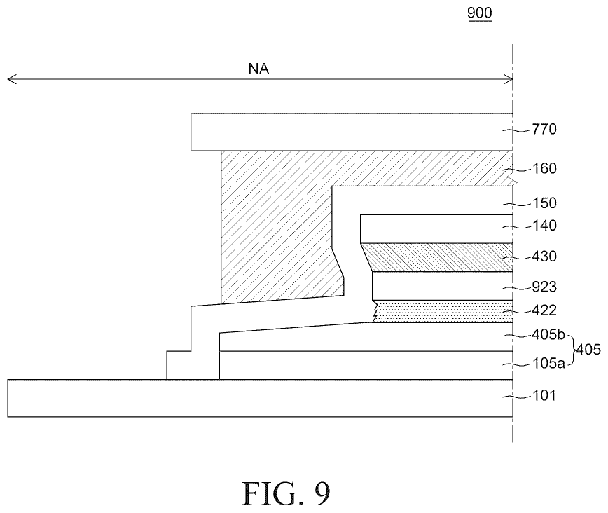

FIG. 9 is a cross-sectional view of a display device according to another embodiment.

In a display device 900 of another embodiment of FIG. 9, a specific shape of a cathode 923 or a relationship between the cathode 923 and its surrounding elements is substantially the same as that of the cathode 423 in the display device 400 of another embodiment of FIG. 4. However, a material for the cathode 923 is substantially the same as that of the cathode 723 in the display device 700 of another embodiment of FIGS. 7 and 8.

In the display device 900 of another embodiment, the ends of the organic layer 422, the cathode 923 and the capping layer 430 are disposed further inward than the first inorganic encapsulation layer 140, so that the surface area of the non-display area NA decreases. Accordingly, the width of the bezel may decrease. Further, although the non-display area NA decreases, moisture-infiltration prevention performance may be maintained or rather increased, while reliability may be secured.

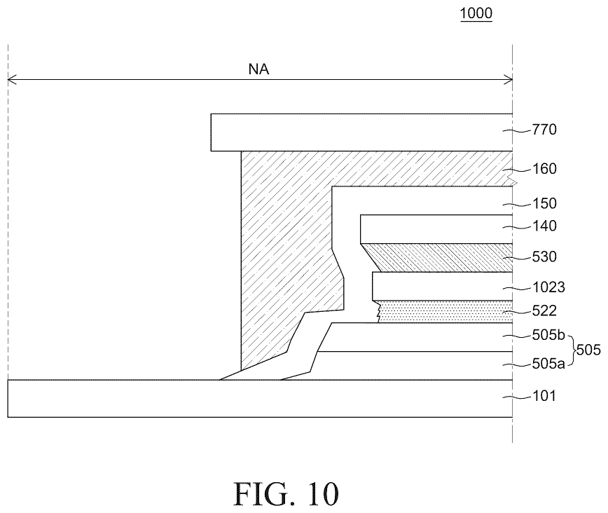

FIG. 10 is a cross-sectional view of a display device according to another embodiment.

In a display device 1000 of another embodiment of FIG. 10, a specific shape of a cathode 1023 or a relationship between the cathode 1023 and its surrounding elements is substantially the same as that of the cathode 523 in the display device 500 of another embodiment of FIG. 5. However, a material for the cathode 1023 is substantially the same as that of the cathode 723 in the display device 700 of another embodiment of FIGS. 7 and 8.

In the display device 1000 of another embodiment, the ends of the organic layer 522, the cathode 1023 and the capping layer 530 are disposed further inward than the first inorganic encapsulation layer 140, and the end of the planarization layer 505 may also be disposed further inward than the planarization layer of the above-described embodiments, so that the surface area of the non-display area NA decreases. For example, the end of the planarization layer 505 may be disposed further inward than the end of the adhesive layer 160. Accordingly, the width of the bezel may decrease. Further, although the non-display area NA decreases, moisture-infiltration prevention performance may be maintained or rather increased, while reliability may be secured.

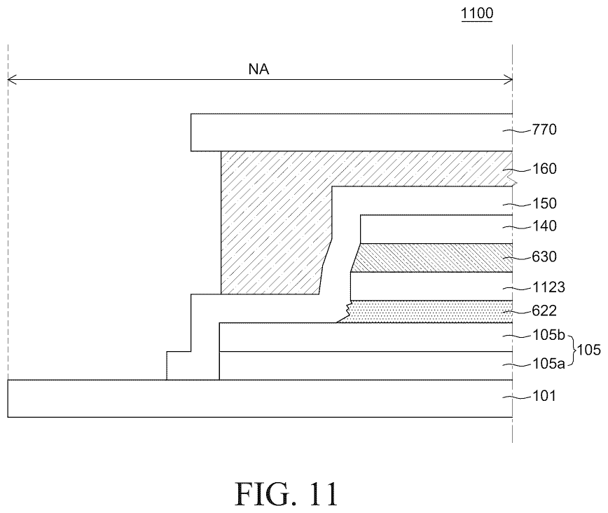

FIG. 11 is a cross-sectional view of a display device according to yet another embodiment.

In a display device 1100 of yet another embodiment of FIG. 11, a specific shape of a cathode 1123 or a relationship between the cathode 1123 and its surrounding elements is substantially the same as that of the cathode 623 in the display device 600 of another embodiment of FIG. 6. However, a material for the cathode 1123 is substantially the same as that of the cathode 723 in the display device 700 of another embodiment of FIGS. 7 and 8.

In the display device 1100 of yet another embodiment, since the organic layer 622, the cathode 1123 and the capping layer 630 are etched in the etch process, the surface area of the non-display area NA may decrease further, and the width of the bezel may decrease further. Additionally, although the non-display area NA decreases, moisture-infiltration prevention performance may be maintained or rather increased, while reliability may be secured.

The exemplary embodiments of the present disclosure can also be described as follows:

According to an embodiment of the present disclosure, there is provided a display device. The display device includes a substrate comprising an display area and a non-display area surrounding the display area, a planarization layer disposed on the substrate, and extended to the non-display area from the display area, an organic layer disposed on the planarization layer, a cathode disposed on the organic layer, a capping layer disposed on the cathode, a first inorganic encapsulation layer disposed on the capping layer, and a second inorganic encapsulation layer disposed on the first inorganic encapsulation layer to contact the first inorganic encapsulation layer, and disposed to contact a side of the planarization layer, a side of the organic layer, a side of the cathode, a side of the capping layer and a side of the first inorganic encapsulation layer.

The side of one or more of the organic layer, the cathode and the capping layer may be disposed on the same planar surface as the side of the first inorganic encapsulation layer.

An end of the first inorganic encapsulation layer may protrude further outward than an end of one or more of the organic layer, the cathode and the capping layer.

An end of the planarization layer may protrude further outward than an end of the organic layer, and an upper surface of the planarization layer may comprise an inclination surface that inclines toward the substrate in an area where the end of the planarization layer protrudes further than the end of the organic layer.

The end of the first inorganic encapsulation layer may protrude further outward than an end of the cathode, and an end of an upper surface of the cathode may protrudes further outward than an end of a lower surface of the capping layer.

An end of an upper surface of the organic layer may protrude further outward than an end of a lower surface thereof.

An end of one or more of the organic layer, the cathode and the capping layer may protrude further outward than an end of the first inorganic encapsulation layer.

An end of the cathode may protrude further outward than the end of the first inorganic encapsulation layer.

A side of the capping layer may incline to protrude outward further toward a lower surface thereof.

An end of an upper surface of the capping layer may be aligned with an end of a lower surface of the first inorganic encapsulation layer, and an end of a lower surface of the capping layer may be aligned with an end of an upper surface of the cathode.

An end of a lower surface of the organic layer may protrude further outward than an end of an upper surface of thereof.

The side of the organic layer may comprise an irregular convex and concave part.

The organic layer may comprise one or more of a light emitting layer, an electron injection layer, an electron transport layer, a hole transport layer and a hole injection layer, and an end of each of the layers may protrude to a different degree.

The display device may further comprise an adhesive layer and an encapsulation substrate disposed on the second inorganic encapsulation layer.

The display device may further comprise a dam disposed to surround the adhesive layer between the substrate and the encapsulation substrate, and a lower surface of the dam may contact the substrate and the second inorganic encapsulation layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate comprising a display area and a non-display area that surrounds the display area;
a planarization layer over the substrate, the planarization layer extending to the non-display area from the display area;
an organic layer on the planarization layer;
a cathode on the organic layer;
a capping layer on the cathode;
a first inorganic encapsulation layer on the capping layer; and
a second inorganic encapsulation layer on the first inorganic encapsulation layer and contacts the first inorganic encapsulation layer, the second inorganic encapsulation layer contacting a side of the planarization layer, a side of the organic layer, a side of the cathode, a side of the capping layer and a side of the first inorganic encapsulation layer.

2. The display device of claim 1, wherein the side of one or more of the organic layer, the cathode, and the capping layer is on a same planar surface as the side of the first inorganic encapsulation layer.

3. The display device of claim 1, wherein an end of the first inorganic encapsulation layer protrudes further outward than an end of one or more of the organic layer, the cathode, and the capping layer.

4. The display device of claim 3, wherein an end of the planarization layer protrudes further outward than an end of the organic layer, and
wherein an upper surface of the planarization layer comprises an inclination surface that inclines toward the substrate in an area where the end of the planarization layer protrudes further than the end of the organic layer.

5. The display device of claim 3, wherein the end of the first inorganic encapsulation layer protrudes further outward than an end of the cathode, and an end of an upper surface of the cathode protrudes further outward than an end of a lower surface of the capping layer.

6. The display device of claim 3, wherein an end of an upper surface of the organic layer protrudes further outward than an end of a lower surface thereof.

7. The display device of claim 1, wherein an end of one or more of the organic layer, the cathode, and the capping layer protrudes further outward than an end of the first inorganic encapsulation layer.

8. The display device of claim 7, wherein an end of the cathode protrudes further outward than the end of the first inorganic encapsulation layer.

9. The display device of claim 7, wherein a side of the capping layer inclines to protrude outward further toward a lower surface thereof.

10. The display device of claim 9, wherein an end of an upper surface of the capping layer is aligned with an end of a lower surface of the first inorganic encapsulation layer, and
wherein an end of a lower surface of the capping layer is aligned with an end of an upper surface of the cathode.

11. The display device of claim 8, wherein an end of a lower surface of the organic layer protrudes further outward than an end of an upper surface of thereof.

12. The display device of claim 1, wherein the side of the organic layer comprises an irregular convex and concave part.

13. The display device of claim 12, wherein the organic layer comprises one or more of a light emitting layer, an electron injection layer, an electron transport layer, a hole transport layer, and a hole injection layer, and an end of each of the light emitting layer, the electron injection layer, the electron transport layer, the hole transport layer, and the hole injection layer protrudes to a different degree.

14. The display device of claim 1, further comprising:
an adhesive layer and an encapsulation substrate on the second inorganic encapsulation layer.

15. The display device of claim 14, further comprising:
a dam that surrounds the adhesive layer between the substrate and the encapsulation substrate, and
wherein a lower surface of the dam contacts the substrate and the second inorganic encapsulation layer.
